(19) United States
(12) Patent Application Publication
(10) Pub. No.: US 2026/0254269 A1
(43) Pub. Date: Aug. 27, 2026

(54) BIDIRECTIONAL CONDUCTION CHIP, CIRCUIT SYSTEM, AND ELECTRONIC DEVICE

(71) Applicant: Shanghai Yaohuo Microelectronics Co., Ltd, Shanghai (CN)

(72) Inventors: Yongjin LUO, Shanghai (CN); Zhimin LIN, Shanghai (CN)

(21) Appl. No.: 19/546,293

(22) Filed: Feb. 21, 2026

(30) Foreign Application Priority Data
Feb. 25, 2025 (CN) 2025102180793

(51) Int. Cl. H02J 7/90; H02J 7/50; H03F 1/52; H03F 3/45

(52) U.S. Cl. CPC H02J 7/90; H02J 7/50; H03F 1/523; H03F 3/45475; H03F 2203/45536

(57) ABSTRACT

Provided are a bidirectional conduction chip, a circuit system, and an electronic device. The chip is integrated with a MOS switching transistor, a first transconductance operational amplifier, a first voltage source, a second transconductance operational amplifier, a second voltage source, and an enabling unit. A first terminal of the MOS switching transistor is connected to a first input pin of the bidirectional conduction chip, a second terminal of the MOS switching transistor is connected to a second input pin of the bidirectional conduction chip, and the MOS switching transistor controls an on/off state of the MOS switching transistor based on a first current or a second current at a gate of the MOS switching transistor.

### CROSS-REFERENCE TO RELATED APPLICATIONS

This application claims priority to the Chinese Patent Application Serial No. 2025102180793, filed Feb. 25, 2025, which is incorporated by reference in its entirety.

### TECHNICAL FIELD

The present invention relates to the field of electronic circuits, and in particular, to a bidirectional conduction chip, a circuit system, and an electronic device.

### BACKGROUND

Currently, with the continuous development of wearable electronic products, some products such as a mobile phone with a foldable screen, a headset, a virtual reality helmet, and smart glasses have increasingly high requirements on power consumption of a circuit. In addition, bidirectional conduction of a current path is also of critical importance.

However, a loss of an existing electronic product on a path and bidirectional conduction of the current path still need to be optimized.

### SUMMARY

Embodiments of the present invention provide a bidirectional conduction chip, a circuit system, and an electronic device, to optimize a path loss and bidirectional conduction of a current path.

To resolve the foregoing technical problem, the technical solutions of the present invention provide a bidirectional conduction chip, and the bidirectional conduction chip is integrated with the following:
a MOS switching transistor, where a first terminal of the MOS switching transistor is connected to a first input pin of the bidirectional conduction chip, a second terminal of the MOS switching transistor is connected to a second input pin of the bidirectional conduction chip, and the MOS switching transistor controls an on/off state of the MOS switching transistor based on a first current or a second current at a gate of the MOS switching transistor;
a first transconductance operational amplifier and a first voltage source, where an output terminal of the first transconductance operational amplifier is connected to the gate of the MOS switching transistor and outputs the first current, an inverting input pin of the first transconductance operational amplifier is connected to the first input pin, a non-inverting input pin of the first transconductance operational amplifier is connected to a positive electrode of the first voltage source, and a negative electrode of the first voltage source is connected to the second input pin;
a second transconductance operational amplifier and a second voltage source, where an output terminal of the second transconductance operational amplifier is also connected to the gate of the MOS switching transistor and outputs the second current, a non-inverting input pin of the second transconductance operational amplifier is connected to a positive electrode of the second voltage source, a negative electrode of the second voltage source is connected to the first input pin, an inverting input pin of the second transconductance operational amplifier is connected to the second input pin, and an output voltage of the second voltage source and an output voltage of the first voltage source are the same and both are used to represent a preset stable voltage between the first input pin and the second input pin; and
an enabling unit, where the enabling unit is configured to:
when a first voltage at the first input pin is greater than a second voltage at the second input pin, output a first enable signal to enable the first transconductance operational amplifier, and output a second enable signal to disable the second transconductance operational amplifier; and
when the first voltage is less than the second voltage, output a second enable signal to enable the second transconductance operational amplifier, and output a first enable signal to disable the first transconductance operational amplifier.

Optionally, the enabling unit includes a first comparator and an inverter, an output terminal of the first comparator is separately connected to an input pin of the inverter and an enabling terminal of the second transconductance operational amplifier, a non-inverting input pin of the first comparator is connected to the second input pin, an inverting input pin of the first comparator is connected to the first input pin, and an output terminal of the inverter is connected to an enabling terminal of the first transconductance operational amplifier; and both the first transconductance operational amplifier and the second transconductance operational amplifier are enabled at a high level.

Optionally, the bidirectional conduction chip further includes a first switch. A first terminal of the first switch is connected to a substrate terminal of the MOS switching transistor, a second terminal of the first switch is connected to the first terminal of the MOS switching transistor, a third terminal of the first switch is connected to the second terminal of the MOS switching transistor, a control terminal of the first switch is connected to the output terminal of the first comparator, and the first switch is configured to:
connect the first terminal and the third terminal of the first switch based on a high level; and
connect the first terminal and the second terminal of the first switch based on a low level.

Optionally, the bidirectional conduction chip further includes a current limiting control module, a constant current regulation module, a constant current regulation pin, and a driving module;
the current limiting control module is configured to output a first control signal to an input terminal of the driving module;
the constant current regulation module is configured to:
output a second control signal to the input terminal of the driving module when the second voltage is less than a precharge threshold voltage;
output a third control signal to the input terminal of the driving module when the second voltage is greater than or equal to the precharge threshold voltage; and
output a fourth control signal to the input terminal of the driving module after a delay of first specified time when the second voltage is greater than or equal to a preset upper-limit voltage;
the constant current regulation pin is connected to a control terminal of the driving module; and
an output terminal of the driving module is connected to the gate of the MOS transistor, and the driving module is configured to:
limit a current from the second input pin to the first input pin within a first current limiting value based on the first control signal;
control a current from the first input pin to the second input pin to be constant at a precharge current based on the second control signal;
control the current from the first input pin to the second input pin to be constant at a preset constant current based on the third control signal and impedance to ground of the constant current regulation pin; and
turn off the MOS switching transistor based on the fourth control signal.

Optionally, the constant current regulation module includes a voltage division unit, a second comparator, and a third comparator;
the voltage division unit is configured to divide the second voltage and output a divided voltage;
both a non-inverting input pin of the second comparator and a non-inverting input pin of the third comparator are connected to the divided voltage, an inverting input pin of the second comparator is connected to a first reference voltage, an inverting input pin of the third comparator is connected to a second reference voltage, an output terminal of the second comparator and an output terminal of the third comparator are both connected to the current limiting control module, the first reference voltage is less than the second reference voltage, the first reference voltage is used to represent the precharge threshold voltage, and the second reference voltage is used to represent the preset upper-limit voltage;
if the divided voltage is less than the first reference voltage, both the second comparator and the third comparator output a low level, and the second control signal includes two low-level signals;
if the divided voltage is greater than or equal to the first reference voltage and less than the second reference voltage, the second comparator outputs a high level, the third comparator outputs a low level, and the third control signal includes one low-level signal and one high-level signal; and
if the divided voltage is greater than or equal to the second reference voltage, both the second comparator and the third comparator output a high level, and the fourth control signal includes two high-level signals.

Optionally, the bidirectional conduction chip further includes a turn-off unit. The turn-off unit is configured to pull the constant current regulation pin to a high level based on a turn-off signal that is externally input to the constant current regulation pin, so that the driving module turns off the MOS switching transistor.

Optionally, the MOS switching transistor is a PMOS transistor, a gate of the PMOS transistor is the gate of the MOS switching transistor, a source of the PMOS transistor is the first terminal of the MOS switching transistor, and a drain of the PMOS transistor is the second terminal of the MOS switching transistor.

Optionally, the MOS switching transistor is an NMOS transistor, a gate of the NMOS transistor is the gate of the MOS switching transistor, a source of the NMOS transistor is the second terminal of the MOS switching transistor, and a drain of the NMOS transistor is the first terminal of the MOS switching transistor;
the chip is further integrated with a charge pump, and the charge pump is configured to improve a capability of driving the gate of the NMOS transistor;
the inverting input pin of the first transconductance operational amplifier is connected to the positive electrode of the first voltage source instead, and the non-inverting input pin of the first transconductance operational amplifier is connected to the first input pin instead; and
the inverting input pin of the second transconductance operational amplifier is connected to the positive electrode of the second voltage source instead, and the non-inverting input pin of the first transconductance operational amplifier is connected to the second input pin instead.

The technical solutions of the present invention further provide a circuit system, including:
two bidirectional conduction chips;
a first battery and a second battery, where the first battery and the second battery each correspond to one of the bidirectional conduction chips, a positive electrode of the first battery and a positive electrode of the second battery each are connected to a second input pin of a corresponding bidirectional conduction chip, and both a negative electrode of the first battery and a negative electrode of the second battery are connected to a ground terminal;
a charging management chip and a system load, where a first pin of the charging management chip is respectively connected to first input pins of the two bidirectional conduction chips, a power input pin of the charging management chip is connected to an externally input power voltage, the charging management chip is configured to perform path management on the power voltage and charge the first battery and the second battery, a power supply terminal of the system load is connected to a second pin of the charging management chip, and the first pin and the second pin of the charging management chip are coupled by using an internal power supply control switch of the charging management chip; and
a first constant current regulation resistor and a second constant current regulation resistor, where the first constant current regulation resistor and the second constant current regulation resistor respectively correspond to one of the bidirectional conduction chips, a first terminal of the first constant current regulation resistor and a first terminal of the second constant current regulation resistor each are connected to a constant current regulation pin of a corresponding bidirectional conduction chip, and both the first terminal of the first constant current regulation resistor and the first terminal of the second constant current regulation resistor are connected to the ground terminal.

The technical solutions of the present invention further provide a circuit system, including:
the bidirectional conduction chip;
a supercapacitor, where a charging terminal of the supercapacitor is connected to a second input pin of the bidirectional conduction chip; and
a charging power supply, where a voltage output terminal of the charging power supply is connected to a first input pin of the bidirectional conduction chip.

The technical solutions of the present invention further provide an electronic device, including any one of the foregoing circuit systems.

Compared with a conventional technology, the technical solutions provided by the present invention have the following beneficial effects:

In the bidirectional conduction chip provided in the technical solutions of the present invention, the bidirectional conduction chip is integrated with the MOS switching transistor, the first transconductance operational amplifier, the first voltage source, the second transconductance operational amplifier, the second voltage source, and the enabling unit. Therefore, when the first voltage is greater than the second voltage, the first transconductance operational amplifier outputs the corresponding first current to the gate of the MOS switching transistor based on a voltage difference between the first input pin and the second input pin, to maintain a difference between the first voltage and the second voltage as the preset stable voltage by controlling the on/off state of the MOS switching transistor. When the first voltage is less than the second voltage, the second transconductance operational amplifier outputs the corresponding second current to the gate of the MOS switching transistor based on a voltage difference between the second input pin and the first input pin, to maintain a difference between the second voltage and the first voltage as the preset stable voltage by controlling the on/off state of the MOS switching transistor. When an absolute value of the difference between the first voltage and the second voltage is less than the preset stable voltage, to maintain the absolute value of the difference between the first voltage and the second voltage as the preset stable voltage, a current is drawn from the gate of the MOS switching transistor until the MOS switching transistor is completely turned off. Therefore, regardless of a current flowing direction, as long as the voltage difference between the first input pin and the second input pin is a low voltage difference, zero-current cutoff between the first input pin and the second input pin can be implemented; and in addition, as long as the voltage difference between the first input pin and the second input pin is greater than the preset stable voltage, the MOS switching transistor can be automatically turned on, thereby implementing bidirectional adaptive low-voltage-difference conduction.

Therefore, the bidirectional conduction chip provided in the present invention can implement bidirectional zero-current cutoff and bidirectional adaptive low-voltage-difference conduction, thereby significantly reducing a system power loss. In addition, because all solutions of the bidirectional conduction chip are implemented by an analog circuit, control resources of the system are saved, and program design costs are reduced.

Further, in the present invention, the first comparator is used to compare the first voltage and the second voltage, and a connection state of the first switch is controlled by using a comparison result. Because the first switch connects the first terminal and the third terminal of the first switch based on a high level, and connects the first terminal and the second terminal of the first switch based on a low level. Therefore, when the first voltage is greater than the second voltage, a cathode of a body diode of the MOS switching transistor is controlled to be connected to the first input pin, and when the first voltage is less than the second voltage, the cathode of the body diode of the MOS switching transistor is controlled to be connected to the second input pin, to ensure that when the MOS switching transistor is turned off, no reverse leakage current is generated due to the body diode of the MOS switching transistor, thereby further reducing a path loss.

Further, through disposing of the current limiting control module, the constant current regulation module, the constant current regulation pin, and the driving module, bidirectional constant current control is implemented between the first input pin and the second input pin, thereby ensuring security of bidirectional current flowing.

In the circuit system provided in the technical solutions of the present invention, because the bidirectional conduction chip can control the on/off state of the MOS switching transistor based on whether the voltage difference between the first input pin and the second input pin is equal to the preset stable voltage, an automatic current flowing path is formed, so that the first battery and the second battery can be adaptively charged or supplied with power based on a relationship between a battery voltage and an external voltage, and a case that a power path cannot be turned on when a battery with a low voltage needs to be charged does not occur.

Because the bidirectional conduction chip can control magnitude of a current flowing between the first input pin and the second input pin, that is, constant current protection can be implemented for currents regardless of whether the first battery or the second battery supplies power to the outside or is charged with a voltage of an external power supply, and precharging, constant current regulation, and overcharge prevention of a battery can be implemented when the first battery or the second battery is charged with the voltage of the external power supply. This not only ensures that no large current occurs when the first battery and the second battery are shorted, preventing path heating or burning of some circuit nodes, but also improves the safety of battery charging and discharging.

In the embodiments of the present invention, because the bidirectional conduction chip enables a battery with a higher voltage to charge a battery with a lower voltage, allows both batteries to supply power to a system load when their battery voltages are equal, and allows a charging management chip to supply power to both batteries simultaneously, battery balancing between the first battery and the second battery is significantly improved.

### BRIEF DESCRIPTION OF DRAWINGS

FIG. 1 is a diagram 1 of a circuit structure of a bidirectional conduction chip according to an embodiment of the present invention;

FIG. 2 is a diagram 2 of a circuit structure of a bidirectional conduction chip according to an embodiment of the present invention;

FIG. 3 is a diagram 3 of a circuit structure of a bidirectional conduction chip according to an embodiment of the present invention;

FIG. 4 is a diagram 4 of a circuit structure of a bidirectional conduction chip according to an embodiment of the present invention; and

FIG. 5 is a schematic diagram of a module structure of a circuit system according to an embodiment of the present invention.

### DESCRIPTION OF EMBODIMENTS

As described in the background, a path loss of an existing electronic product still needs to be optimized.

In view of this, a new bidirectional conduction chip is provided in embodiments of the present invention, to optimize a path loss or adaptive bidirectional conduction.

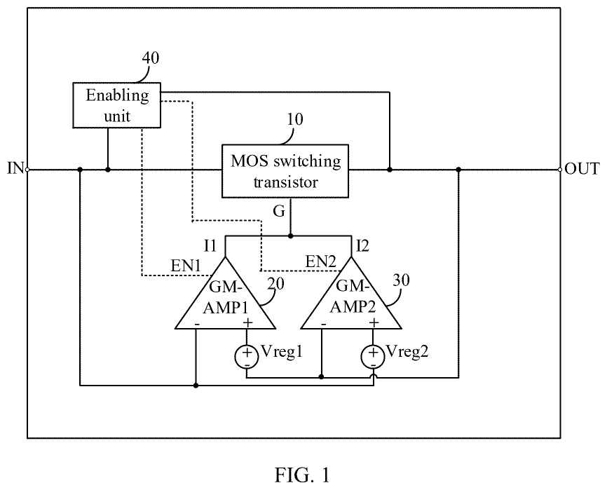

FIG. 1 is a diagram 1 of a circuit structure of a bidirectional conduction chip according to an embodiment of the present invention.

As shown in FIG. 1, the bidirectional conduction chip provided in this embodiment of the present invention includes:
a MOS switching transistor 10, where a first terminal of the MOS switching transistor 10 is connected to a first input pin IN of the bidirectional conduction chip, a second terminal of the MOS switching transistor 10 is connected to a second input pin OUT of the bidirectional conduction chip, and the MOS switching transistor 10 controls an on/off state of the MOS switching transistor based on a first current I1 or a second current I2 at a gate of the MOS switching transistor;
a first transconductance operational amplifier 20 and a first voltage source Vreg1, where an output terminal of the first transconductance operational amplifier 20 is connected to the gate of the MOS switching transistor 10, an inverting input pin of the first transconductance operational amplifier 20 is connected to the first input pin IN, a non-inverting input pin of the first transconductance operational amplifier 20 is connected to a positive electrode of the first voltage source Vreg1, and a negative electrode of the first voltage source Vreg1 is connected to the second input pin OUT;
a second transconductance operational amplifier 30 and a second voltage source Vreg2, where an output terminal of the second transconductance operational amplifier 30 is also connected to the gate of the MOS switching transistor 10, a non-inverting input pin of the second transconductance operational amplifier 30 is connected to a positive electrode of the second voltage source Vreg2, a negative electrode of the second voltage source Vreg2 is connected to the first input pin IN, an inverting input pin of the second transconductance operational amplifier 30 is connected to the second input pin OUT, and an output voltage of the second voltage source Vreg2 and an output voltage of the first voltage source Vreg1 are the same and both are used to represent a preset stable voltage between the first input pin IN and the second input pin OUT; and
an enabling unit 40, where the enabling unit 40 is configured to:
when a first voltage at the first input pin IN is greater than a second voltage at the second input pin OUT, output a first enable signal EN1 to enable the first transconductance operational amplifier 20, and output a second enable signal EN2 to disable the second transconductance operational amplifier 30; and
when the first voltage is less than the second voltage, output a second enable signal EN2 to enable the second transconductance operational amplifier 30, and output a first enable signal EN1 to disable the first transconductance operational amplifier 20.

Before beneficial effects of the embodiments of the present invention are described, a working principle of a transconductance operational amplifier needs to be briefly described first.

The transconductance operational amplifier outputs, based on a voltage difference between a non-inverting input pin and an inverting input pin of the transconductance operational amplifier, a current that is proportional to the voltage difference. A specific formula is as follows:

$$Iout = gm ( V + - V - ) ; \qquad Formula ( 1 )$$

Iout is used to represent the current, gm is used to represent transconductance of the transconductance operational amplifier, V+ is used to represent a voltage at the non-inverting input pin, and V− is used to represent a voltage at the inverting input pin.

It may be learned from Formula (1) that when the voltage at the non-inverting input pin is greater than the voltage at the inverting input pin, the current is a positive, that is, the transconductance operational amplifier outputs a current to the outside. When the voltage at the non-inverting input pin is less than the voltage at the inverting input pin, the current is negative, that is, the transconductance operational amplifier extracts a current from the outside.

As shown in FIG. 1, for ease of description, the beneficial effects of the embodiments of the present invention are described in detail below by using a PMOS transistor as an example of the MOS switching transistor.

In this embodiment of the present invention, in the foregoing technical solution, regardless of a current flowing direction, as long as a voltage difference between the first input pin IN and the second input pin OUT is a low voltage difference, zero-current cutoff between the first input pin IN and the second input pin OUT can be implemented, thereby significantly reducing a path loss. Specific reasons are as follows:

The output terminal of the first transconductance operational amplifier 20 is connected to a gate of the PMOS transistor, and outputs the first current I1, and a formula of the first current I1 may be obtained based on the foregoing description as follows:

$$I 1 = gm 1 ( V 1 + - V 1 - ) ; \qquad Formula ( 2 )$$

I1 is used to represent the first current, gm1 is used to represent transconductance of the first transconductance operational amplifier 20, V1+ is used to represent a voltage at the non-inverting input pin of the first transconductance operational amplifier 20, and V1− is used to represent a voltage at the inverting input pin of the first transconductance operational amplifier 20.

Because the inverting input pin of the first transconductance operational amplifier 20 is connected to the first input pin IN, the non-inverting input pin of the first transconductance operational amplifier 20 is connected to the positive electrode of the first voltage source Vreg1, and the negative electrode of the first voltage source Vreg1 is connected to the second input pin OUT, the formula of the first current I1 is modified as follows:

$$I 1 = gm 1 * [ Vreg 1 - ( VIN - VOUT ) ] ; \qquad Formula ( 3 )$$

Vreg1 is used to represent the output voltage of the first voltage source, that is, the preset stable voltage, VIN is used to represent the first voltage at the first input pin IN, and VOUT is used to represent the second voltage at the second input pin OUT.

When the first voltage is greater than the second voltage, a current flows from the first input pin IN to the second input pin OUT. If the current is extremely small to enable the voltage difference between the first input pin IN and the second input pin OUT to be less than the preset stable voltage, because the first transconductance operational amplifier 20 is enabled and the second transconductance operational amplifier 30 is disabled in this case, the first transconductance operational amplifier 20 outputs the first current I1, and it may be learned, based on Formula (3), that the first current I1 is positive, so as to inject a current into the gate of the PMOS transistor. Because the injected current charges a capacitor at the gate of the PMOS transistor, a voltage of the gate is increased, so that the PMOS transistor tends to be turned off to increase impedance of the PMOS transistor. An increase in the impedance of the PMOS transistor can increase the voltage difference between the first input pin IN and the second input pin OUT, so that the difference approaches the preset stable voltage until the PMOS transistor is completely turned off to cut off the current flowing from the first input pin IN to the second input pin OUT, thereby reducing a path loss. If the current is extremely large to enable the voltage difference between the first input pin IN and the second input pin OUT to be greater than the preset stable voltage, it may be learned, based on Formula (3), that the first current I1 is negative, so as to extract a current from the gate of the PMOS transistor. Because the extracted current discharges the capacitor at the gate of the PMOS transistor, the voltage at the gate is reduced, so that the PMOS transistor tends to be turned on to decrease the impedance of the PMOS transistor. A decrease in the impedance of the PMOS transistor can decrease the voltage difference between the first input pin IN and the second input pin OUT, so that the difference approaches the preset stable voltage until the PMOS transistor is completely turned on.

In addition to the first transconductance operational amplifier 20, the output terminal of the second transconductance operational amplifier 30 is also connected to the gate of the PMOS transistor and outputs the second current I2. It may be learned based on the foregoing description that a formula of the second current I2 is as follows:

$$I 2 = gm 2 * ( V 2 + - V 2 - ) ; \qquad Formula ( 3 )$$

I2 is used to represent the second current, gm2 is used to represent transconductance of the second transconductance operational amplifier 30, V2+ is used to represent a voltage at the non-inverting input pin of the second transconductance operational amplifier 30, and V2− is used to represent a voltage at the inverting input pin of the second transconductance operational amplifier 30.

Because the inverting input pin of the second transconductance operational amplifier 30 is connected to the second input pin OUT, the non-inverting input pin of the second transconductance operational amplifier 30 is connected to the positive electrode of the second voltage source Vreg2, and the negative electrode of the second voltage source Vreg2 is connected to the first input pin IN, the formula of the second current I2 is modified as follows:

$$I 2 = gm 2 * [ Vreg 2 - ( VOUT - VIN ) ] ; \qquad Formula ( 4 )$$

Vreg2 is used to represent the output voltage of the second voltage source, that is, the preset stable voltage.

When the first voltage is less than the second voltage, a current flows from the second input pin OUT to the first input pin IN. If the current is extremely small to enable the voltage difference between the second input pin OUT and the first input pin IN to be less than the preset stable voltage, because the second transconductance operational amplifier 30 is enabled and the first transconductance operational amplifier 20 is disabled in this case, the second transconductance operational amplifier 30 outputs the second current I2, and it may be learned, based on Formula (4), that the second current I2 is positive, so as to inject a current into the gate of the PMOS transistor, so that the PMOS transistor tends to be turned off to increase impedance of the PMOS transistor. An increase in the impedance of the PMOS transistor can increase the voltage difference between the second input pin OUT and the first input pin IN, so that the difference approaches the preset stable voltage until the PMOS transistor is completely turned off to cut off the current flowing from the second input pin OUT to the first input pin IN, thereby reducing a path loss. If the current is extremely large to enable the voltage difference between the second input pin OUT and the first input pin IN to be greater than the preset stable voltage, it may be learned, based on Formula (4), that the second current I2 is negative, so as to extract a current from the gate of the PMOS transistor, so that the PMOS transistor tends to be turned on to decrease impedance of the PMOS transistor. A decrease in the impedance of the PMOS transistor can decrease the voltage difference between the second input pin OUT and the first input pin IN, so that the difference approaches the preset stable voltage until the PMOS transistor is completely turned on.

Therefore, the bidirectional conduction chip provided in the present invention can implement bidirectional zero-current cutoff and bidirectional adaptive low-voltage-difference conduction, thereby significantly reducing a system power loss. In addition, because all solutions of the bidirectional conduction chip are implemented by an analog circuit, control resources of the system are saved, and program design costs are reduced.

In summary, the bidirectional conduction chip provided in the embodiments of the present invention, through bidirectional modulation by two transconductance operational amplifiers, implements diode-like forward-conduction voltage-drop modulation and zero-current reverse-current control in both directions: from the first input pin to the second input pin, and from the second input pin to the first input pin. A chip that exhibits diode-like function obtained through such modulation control is referred to as an ideal diode; therefore, the circuit architecture provided in the present invention is essentially a bidirectional ideal diode.

To make the foregoing objectives, features, and beneficial effects of the present invention more clear and easier to understand, the technical solutions in the embodiments of the present invention are clearly and completely described below with reference to the accompanying drawings in the embodiments of the present invention. Clearly, the described embodiments are merely some rather than all of the embodiments of the present invention. All other embodiments obtained by a person of ordinary skill in the art based on the embodiments of the present invention without creative efforts shall fall within the protection scope of the present invention. Terms “first”, “second”, “third”, “fourth”, and the like (if they exist) in the description, claims, and the foregoing accompanying drawings of the present invention are used for distinguishing similar objects and not for describing a specific order or sequence. It should be understood that the terms used in this way may be interchanged where appropriate, so that the embodiments of the present invention described herein can be implemented in a sequence other than what is illustrated or described herein. In addition, terms “include” and “have” and any variations thereof are intended to cover non-exclusive inclusion, for example, processes, methods, systems, products, or devices that contain a series of steps or units are not necessarily limited to those steps or units that are clearly listed, but may include other steps or units that are not clearly listed or are inherent to these processes, methods, products, or devices.

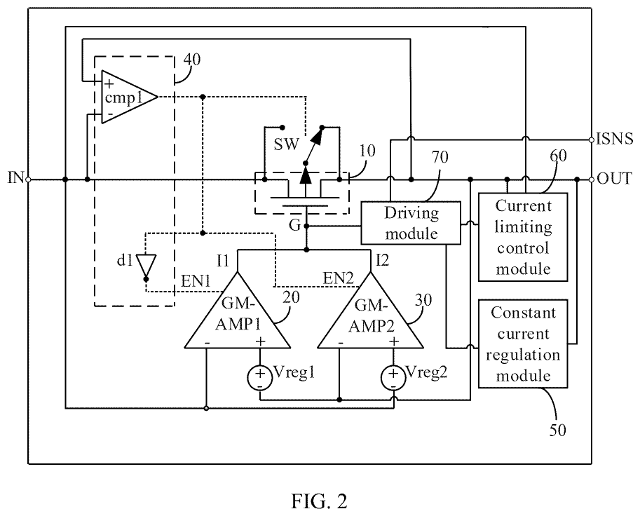

FIG. 2 is a diagram 2 of a circuit structure of a bidirectional conduction chip according to an embodiment of the present invention.

Referring to FIG. 2, in a specific implementation, the enabling unit 40 includes a first comparator cmp1 and an inverter d1. An output terminal of the first comparator cmp1 is separately connected to an input pin of the inverter d1 and an enabling terminal of the second transconductance operational amplifier 30, a non-inverting input pin of the first comparator cmp1 is connected to the second input pin OUT, an inverting input pin of the first comparator cmp1 is connected to the first input pin IN, and an output terminal of the inverter d1 is connected to an enabling terminal of the first transconductance operational amplifier 20.

Both the first transconductance operational amplifier 20 and the second transconductance operational amplifier 30 are enabled at a high level.

It should be supplemented that, to avoid oscillation caused by repeatedly enabling and disabling the first transconductance operational amplifier and the second transconductance operational amplifier during enabling of the first transconductance operational amplifier and the second transconductance operational amplifier, specific voltage hysteresis exists in an output signal of the first comparator.

Referring to FIG. 2, regardless of whether a current flows from the first input pin IN to the second input pin OUT or from the second input pin OUT to the first input pin IN, to ensure zero-current cutoff between the first input pin IN and the second input pin OUT when the voltage difference between the first input pin IN and the second input pin OUT is less than the preset stable voltage, current leakage of a body diode of the MOS switching transistor 10 needs to be taken into consideration. Therefore, in a specific implementation, this embodiment of the present invention further provides a first switch SW. A first terminal of the first switch SW is connected to a substrate terminal of the MOS switching transistor 10, a second terminal of the first switch SW is connected to the first terminal of the MOS switching transistor 10, a third terminal of the first switch SW is connected to the second terminal of the MOS switching transistor 10, and a control terminal of the first switch SW is connected to the output terminal of the first comparator cmp1. For example, the MOS switching transistor 10 is a PMOS transistor. When the first voltage is greater than the second voltage, the first comparator cmp1 outputs a low level to act on the control terminal of the first switch SW, and the first switch SW connects the first terminal and the second terminal of the first switch SW, thereby connecting a substrate and a source of the PMOS transistor. Therefore, a cathode of a body diode of the PMOS transistor is connected to the source of the PMOS transistor, and an anode is connected to a drain of the PMOS transistor, so as to prevent a current from flowing from the first input pin IN to the second input pin OUT through the body diode, thereby achieving true zero-current cutoff. When the first voltage is less than the second voltage, the first comparator cmp1 outputs a high level to act on the control terminal of the first switch SW, and the first switch SW connected to the first terminal and the third terminal of the first switch SW, thereby connecting the substrate and the drain of the PMOS transistor. Therefore, the cathode of the body diode of the PMOS transistor is connected to the drain of the PMOS transistor, and the anode is connected to the source of the PMOS transistor, so as to prevent a current from flowing from the second input pin OUT to the first input pin IN through the body diode, thereby achieving true zero-current cutoff. Therefore, the bidirectional conduction chip provided in this embodiment implements bidirectional zero-current cutoff in both directions: from the first input pin IN to the second input pin OUT, and from the second input pin OUT to the first input pin IN.

Specifically, the first switch SW may adopt an existing single-pole double-throw switch. Certainly, in addition to the single-pole double-throw switch, other circuit structures or electronic components that have a function of the first switch SW also fall within the protection scope of the present invention, which is not limited herein.

Referring to FIG. 2, when the voltage difference between the first input pin IN and the second input pin OUT is far greater than the preset stable voltage, it may be learned from the foregoing description that the MOS switching transistor 10 is completely turned on, so that a current flows between the first input pin IN and the second input pin OUT. If the flowing current is excessively large, circuit components respectively connected to the first input pin IN and the second input pin OUT are damaged. Therefore, in a specific implementation, this embodiment of the present invention further includes a current limiting control module 60, a constant current regulation module 50, a constant current regulation pin ISNS, and a driving module 70.

The current limiting control module 60 is configured to output a first control signal to an input terminal of the driving module 70.

The constant current regulation module 50 is configured to:
output a second control signal to the input terminal of the driving module 70 when the second voltage is less than a precharge threshold voltage;
output a third control signal to the input terminal of the driving module 70 when the second voltage is greater than or equal to the precharge threshold voltage; and
output a fourth control signal to the input terminal of the driving module 70 after a delay of first specified time when the second voltage is greater than or equal to a preset upper-limit voltage. The first specified time is to prevent the constant current regulation module 50 from oscillating between a high level and a low level in its output of the fourth control signal when the second voltage fluctuates around the preset upper-limit voltage. The first specified time may be specifically set based on a requirement, and is, for example, 3 min to 5 min, which is not limited herein.

The constant current regulation pin ISNS is connected to a control terminal of the driving module 70.

An output terminal of the driving module 70 is connected to the gate of the MOS transistor.

When a current flowing from the second input pin OUT to the first input pin IN exceeds a first current limiting value, the driving module 70 increases impedance of the MOS switching transistor 10 based on the first control signal, so that the current flowing from the second input pin OUT to the first input pin IN is limited to the first current limiting value. The first current limiting value may be adaptively set based on an actual application scenario. For example, in a scenario in which a battery supplies power to a load, the first current limiting value may be set to approximately 2 A. The first current limiting value is not limited herein.

When the second voltage is less than the precharge threshold voltage, the driving module 70 adjusts the impedance of the MOS switching transistor 10 based on the second control signal, so that a current from the first input pin IN to the second input pin OUT is constant at a precharge current.

Before performing high-current fast charging, a battery needs to ensure that a voltage of the battery reaches a precharge threshold voltage for fast charging, to improve charging efficiency. Therefore, a small precharge current needs to be applied to the battery before the voltage of the battery reaches the precharge threshold voltage. Once the voltage of the battery is greater than the precharge threshold voltage, the battery is charged with a large constant-current through fast charging. The precharge threshold voltage of the battery is usually approximately 2.8 V, and the precharge current of the battery is approximately 5 mA. Therefore, both the precharge threshold voltage and the precharge current are determined by a to-be-charged device connected to the second input pin OUT. This is not limited herein.

When the second voltage exceeds the precharge threshold voltage, the driving module 70 adjusts the impedance of the MOS switching transistor 10 based on the third control signal and by using impedance to ground of the constant current regulation pin ISNS, so that the current flowing from the first input pin IN to the second input pin OUT is constant at a preset constant current.

Magnitude of the preset constant current value is specifically set by using magnitude of the impedance to ground of the constant current regulation pin ISNS, and the magnitude of the impedance to ground of the constant current regulation pin ISNS is specifically controlled by an off-chip current detection resistor. Therefore, in different application scenarios, different off-chip current detection resistors may be selected to set the preset constant current. For example, when the battery is charged with a constant current, the preset constant current may be set between dozens of mA and 2 A. This is not limited herein.

When the second voltage is greater than or equal to the preset upper-limit voltage, the driving module 70 turns off the MOS switching transistor 10 based on the fourth control signal, thereby avoiding damage to a component connected to the second input pin OUT. For example, if the second input pin OUT is connected to the battery, when the battery reaches the preset upper-limit voltage, for example, 4.2 V, charging of the battery needs to be stopped, thereby avoiding overcharging of the battery. The preset upper-limit voltage may be adaptively set based on a specific component connected to the second input pin OUT. This is not limited herein.

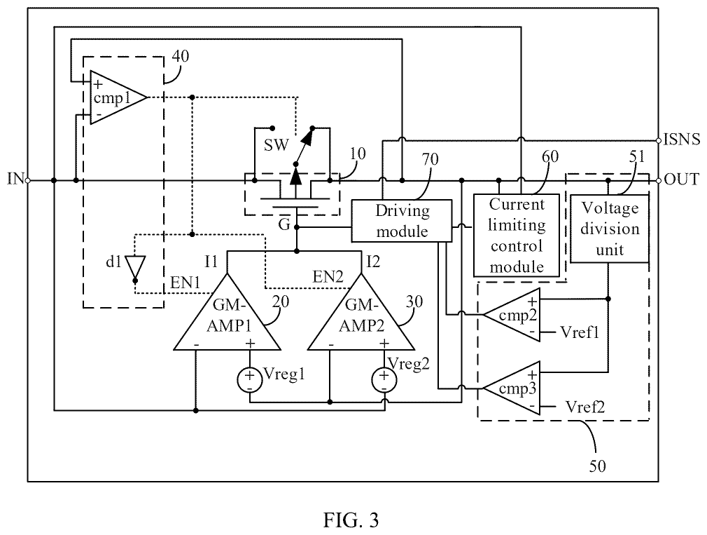

FIG. 3 is a diagram 3 of a circuit structure of a bidirectional conduction chip according to an embodiment of the present invention.

Referring to FIG. 3, specifically, the constant current regulation module 50 includes a voltage division unit 51, a second comparator cmp2, and a third comparator cmp3.

The voltage division unit 51 is configured to divide the second voltage and output a divided voltage. The voltage division unit 51 may specifically include a voltage division resistor circuit, or may include another circuit that has a voltage division function. This is not limited herein.

Both a non-inverting input pin of the second comparator cmp2 and a non-inverting input pin of the third comparator cmp3 are connected to the divided voltage, an inverting input pin of the second comparator cmp2 is connected to a first reference voltage Vref1, an inverting input pin of the third comparator cmp3 is connected to a second reference voltage Vref2, an output terminal of the second comparator cmp2 and an output terminal of the third comparator cmp3 are both connected to the current limiting control module, the first reference voltage Vref1 is less than the second reference voltage Vref2, the first reference voltage Vref1 is used to represent the precharge threshold voltage, and the second reference voltage Vref2 is used to represent the preset upper-limit voltage.

If the divided voltage is less than the first reference voltage Vref1, both the second comparator cmp2 and the third comparator cmp3 output a low level, and the second control signal includes two low-level signals.

If the divided voltage is greater than or equal to the first reference voltage Vref1 and less than the second reference voltage Vref2, the second comparator cmp2 outputs a high level, the third comparator cmp3 outputs a low level, and the third control signal includes one low-level signal and one high-level signal.

If the divided voltage is greater than or equal to the second reference voltage Vref2, both the second comparator cmp2 and the third comparator cmp3 output a high level, and the fourth control signal includes two high-level signals.

Specifically, both the current limiting control module 60 and the driving module 70 can use a conventional technical means in the art, and details are not described herein again.

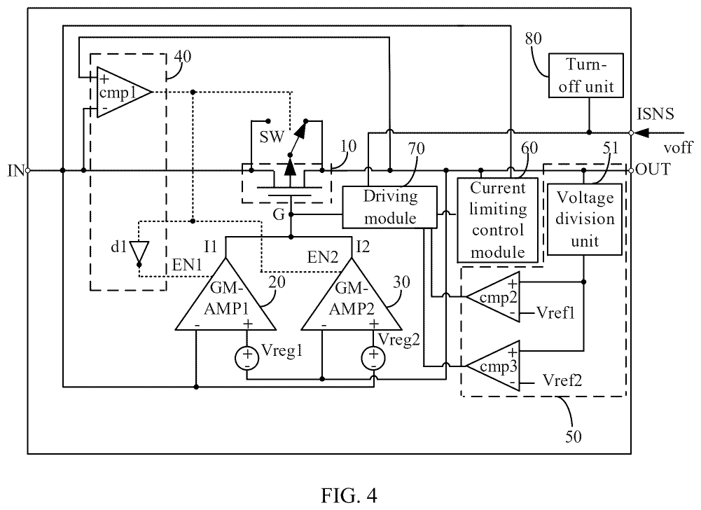

FIG. 4 is a diagram 4 of a circuit structure of a bidirectional conduction chip according to an embodiment of the present invention.

Referring to FIG. 4, in a specific implementation, to improve a control capability of the bidirectional conduction chip, a turn-off unit 80 is further disposed in this embodiment of the present invention. The turn-off unit 80 is configured to force, based on a turn-off signal voff that is externally input to the constant current regulation pin, to pull the constant current regulation pin ISNS to a high level, so that the driving module 70 turns off the MOS switching transistor 10. The turn-off unit 80 specifically includes a turn-off comparator. For example, the MOS switching transistor 10 is a PMOS transistor. A non-inverting input terminal of the turn-off comparator is connected to the constant current regulation pin ISNS, and an inverting input terminal of the turn-off comparator is connected to a third reference voltage. If the MOS switching transistor 10 needs to be turned off by using the constant current regulation pin ISNS, the constant current regulation pin ISNS is pulled high by an externally connected logic high level, and an externally input logic high level is higher than the third reference voltage. Therefore, the turn-off comparator outputs a high level to the driving module, so that the driving module turns off the MOS switching transistor 10.

Certainly, in addition to the turn-off comparator, the turn-off unit 80 may further include a pull-up current source. A negative electrode of the pull-up current source is connected to the constant current regulation pin ISNS, and a positive electrode of the pull-up current source is connected to an internal high level of a chip. Still as an example, the MOS switching transistor 10 is a PMOS transistor. When the MOS switching transistor 10 needs to be turned off, a connection between the constant current regulation pin ISNS and a ground terminal needs to be externally cut off, so that the constant current regulation pin is pulled up to a logic high level by the pull-up current source. In this case, the turn-off comparator outputs a high level to the driving module, so that the driving module turns off the MOS switching transistor 10.

It should be added that, an output terminal of the turn-off comparator may be directly connected to the gate of the MOS switching transistor in addition to the driving module. For example, if the MOS switching transistor is a PMOS transistor, the turn-off comparator outputs a level to a gate of the PMOS transistor, to directly turn off the PMOS transistor.

It should be noted that, if the MOS switching transistor is an NMOS transistor, to match a driving principle of the NMOS transistor, objects respectively connected to the non-inverting input terminal and the inverting input terminal of the turn-off comparator are interchanged. A connection relationship and a control manner of another structure remain unchanged. Details are not described herein again.

In a specific implementation, the MOS switching transistor 10 is a PMOS transistor, a gate of the PMOS transistor is the gate of the MOS switching transistor 10, a source of the PMOS transistor is the first terminal of the MOS switching transistor 10, and a drain of the PMOS transistor is the second terminal of the MOS switching transistor 10.

Certainly, in addition to the PMOS transistor, the MOS switching transistor 10 may be replaced with an NMOS transistor and a charge pump. A gate of the NMOS transistor is the gate of the MOS switching transistor 10, a source of the NMOS transistor is the second terminal of the MOS switching transistor 10, a drain of the NMOS transistor is the first terminal of the MOS switching transistor 10, and the charge pump is configured to improve a capability of driving the gate of the NMOS transistor. A specific principle of improving the capability of driving the gate of the NMOS transistor is as follows: An output voltage of the charge pump is separately connected to a power supply terminal of the first transconductance operational amplifier, a power supply terminal of the second transconductance operational amplifier, a power supply terminal of the driving module, and a power supply terminal of the current limiting control module, to increase respective operating voltages of the first transconductance operational amplifier, the second transconductance operational amplifier, the driving module, and the current limiting control module, thereby improving respective capability of the first current, the second current, and the output voltage of the driving module for driving the gate of the NMOS transistor.

It should be noted that if the MOS switching transistor 10 is replaced with the NMOS transistor and the charge pump, the inverting input pin of the first transconductance operational amplifier 20 is connected to the positive electrode of the first voltage source Vreg1 instead, the non-inverting input pin of the first transconductance operational amplifier 20 is connected to the first input pin IN instead, the inverting input pin of the second transconductance operational amplifier 30 is connected to the positive electrode of the second voltage source Vreg2 instead, and the non-inverting input pin of the second transconductance operational amplifier 20 is connected to the second input pin OUT instead. Except that a control principle for the NMOS transistor is opposite to that for the PMOS transistor, an overall circuit working principle of replacing the MOS switching transistor 10 with the NMOS transistor is the same as that in a case that the MOS switching transistor 10 is the PMOS transistor. Details are not described herein again.

It should be noted that the NMOS transistor or the PMOS transistor provided in the embodiments of the present invention is bi-directionally symmetrical in structure. Therefore, pins connected to a source and a drain of the NMOS transistor or the PMOS transistor are not limited. For example, the drain of the NMOS transistor may be connected to the first input pin or the second input pin. The drain of the PMOS transistor may also be connected to the first input pin or the second input pin.

It should be supplemented that, in addition to an externally input supply voltage, each circuit module in the bidirectional conduction chip may further be powered by the first voltage on the first input pin or the second voltage on the second input pin. A specific technical means is as follows: A power supply module in the bidirectional conduction chip is separately connected to the first input pin and the second input pin, and an anti-backflow diode is disposed between the power supply module and the first input pin and between the power supply module and the second input pin, an anode of the anti-backflow diode is connected to the first input pin or the second input pin, and a cathode of the anti-backflow diode is connected to the power supply module, to prevent a current of the power supply module from backflowing to the first input pin or the second input pin. A specific structure of the power supply module may be a conventional technical means in the art, for example, a capacitor. Details are not described herein again.

In conclusion, according to the bidirectional conduction chip provided in the embodiments of the present invention, the enabling unit is disposed to enable the first transconductance operational amplifier or the second transconductance operational amplifier and disable the second transconductance operational amplifier or the first transconductance operational amplifier based on a magnitude relationship between the first voltage and the second voltage. On and off of the MOS switching transistor are controlled by using a mechanism of maintaining the voltage difference between the first input pin and the second input pin as the preset stable voltage by using the first transconductance operational amplifier and the first voltage source and the second transconductance operational amplifier and the second voltage source. Therefore, regardless of a current flowing direction, as long as the voltage difference between the first input pin and the second input pin is a low voltage difference, zero-current cutoff between the first input pin and the second input pin can be implemented; and in addition, as long as the voltage difference between the first input pin and the second input pin is greater than the preset stable voltage, the MOS switching transistor can be automatically turned on, thereby implementing bidirectional adaptive low-voltage-difference conduction. Therefore, the bidirectional conduction chip provided in the present invention can implement bidirectional zero-current cutoff and bidirectional adaptive low-voltage-difference conduction, thereby significantly reducing a system power loss. In addition, because all solutions of the bidirectional conduction chip are implemented by an analog circuit, control resources of the system are saved, and program design costs are reduced.

In summary, the bidirectional conduction chip provided in the embodiments of the present invention, through bidirectional modulation by two transconductance operational amplifiers, implements diode-like forward-conduction voltage-drop modulation and zero-current reverse-current control in both directions: from the first input pin to the second input pin, and from the second input pin to the first input pin. A chip that exhibits diode-like function obtained through such modulation control is referred to as an ideal diode; therefore, the circuit architecture provided in the present invention is essentially a bidirectional ideal diode.

Further, in the present invention, the first comparator is used to compare the first voltage and the second voltage, and a connection state of the first switch is controlled by using a comparison result. Because the first switch connects the first terminal and the third terminal of the first switch based on a high level, and connects the first terminal and the second terminal of the first switch based on a low level. Therefore, when the first voltage is greater than the second voltage, a cathode of a body diode of the MOS switching transistor is controlled to be connected to the first input pin, and when the first voltage is less than the second voltage, the cathode of the body diode of the MOS switching transistor is controlled to be connected to the second input pin, to ensure that when the MOS switching transistor is turned off, no reverse leakage current is generated due to the body diode of the MOS switching transistor, thereby further reducing a path loss.

Further, through disposing of the current limiting control module, the constant current regulation module, the constant current regulation pin, and the driving module, bidirectional constant current control is implemented between the first input pin and the second input pin, thereby ensuring security of bidirectional current flowing.

Based on the bidirectional conduction chip provided in the foregoing embodiments, an embodiment of the present invention further provides a circuit system.

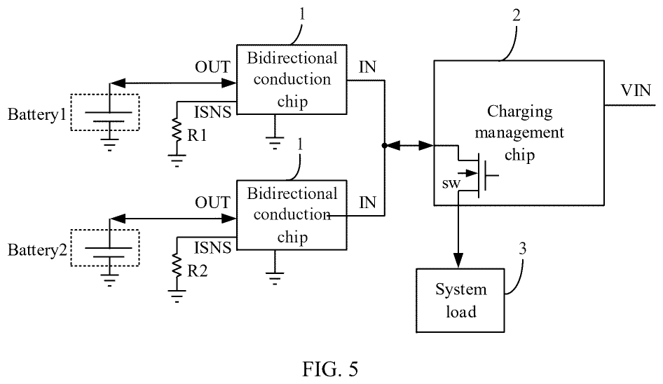

FIG. 5 is a schematic diagram of a module structure of a circuit system according to an embodiment of the present invention.

Referring to FIG. 5, the circuit system provided in this embodiment of the present invention includes the following structures:
two bidirectional conduction chips 1 provided in the foregoing embodiments;
a first battery Battery1 and a second battery Battery2, where the first battery Battery1 and the second battery Battery2 each correspond to one of the bidirectional conduction chips 1, a positive electrode of the first battery Battery1 and a positive electrode of the second battery Battery2 each are connected to a second input pin OUT of a corresponding bidirectional conduction chip 1, and both a negative electrode of the first battery Battery1 and a negative electrode of the second battery Battery2 are connected to a ground terminal;
a charging management chip 2 and a system load 3, where a first pin of the charging management chip 2 is respectively connected to first input pins IN of the two bidirectional conduction chips 1, a power input pin VIN of the charging management chip 2 is connected to an externally input power voltage, the charging management chip 2 is configured to perform path management on the power voltage and charge the first battery Battery1 and the second battery Battery2, a power supply terminal of the system load 3 is connected to a second pin of the charging management chip 2, and the first pin and the second pin of the charging management chip 2 are coupled by using an internal power supply control switch sw of the charging management chip; where the power supply control switch sw may specifically include an NMOS transistor; and
a first constant current regulation resistor R1 and a second constant current regulation resistor R2, where the first constant current regulation resistor R1 and the second constant current regulation resistor R2 respectively correspond to one of the bidirectional conduction chips 1, a first terminal of the first constant current regulation resistor R1 and a first terminal of the second constant current regulation resistor R2 each are connected to a constant current regulation pin ISNS of a corresponding bidirectional conduction chip 1, and both the first terminal of the first constant current regulation resistor R1 and the first terminal of the second constant current regulation resistor R2 are connected to the ground terminal.

A working principle of the circuit system provided in this embodiment of the present invention is described below.

When the power input pin VIN is not connected to an externally input power supply voltage, one of the first battery Battery1 and the second battery Battery2 with a higher battery voltage is turned on to a MOS switching transistor in the bidirectional conduction chip 1. In addition, because the first input pin IN of the bidirectional conduction chip 1 is coupled to the power supply terminal of the system load 3 by using the power supply control switch sw in the charging management chip 2, a power supply path from the battery with the higher battery voltage to the system load 3 is established, to supply power to the system load 3. In addition, if a pull current of the system load 3 on the first input pin IN is insufficient, and a battery voltage of a large battery is large enough, so that a battery voltage difference between the first battery Battery1 and the second battery Battery2 is greater than the preset stable voltage, a MOS switching transistor in a bidirectional conduction chip 1 corresponding to a battery with a smaller battery voltage is turned on because a voltage difference between the first input pin IN and the second input pin OUT is greater than the preset stable voltage, so that the large battery charges the small battery while supplying power to the system load 3. In addition, when the small battery is charged, a charging current is controlled by a constant current of the bidirectional conduction chip 1, thereby ensuring charging safety. If a battery voltage of the first battery Battery1 is equal to a battery voltage of the second battery Battery2, the two batteries may supply power to the system load 3 simultaneously.

When the power input pin VIN is connected to an externally input power voltage, the externally input power voltage is connected to first input pins IN of the two bidirectional conduction chips 1 based on the first pin of the charging management chip 2, and charges the first battery Battery1 and the second battery Battery2 simultaneously based on a working principle of the bidirectional conduction chip 1 until charging of the first battery and the second battery is completed.

Beneficial effects of the circuit system provided in this embodiment of the present invention are described in detail below.

Because the bidirectional conduction chip 1 can control the on/off state of the MOS switching transistor based on whether the voltage difference between the first input pin IN and the second input pin OUT is equal to the preset stable voltage, an automatic current flowing path is formed, so that the first battery Battery1 and the second battery Battery2 can implement adaptive charging or power supply based on a relationship between a battery voltage and an external voltage, and a case that a power path cannot be turned on when a battery with a low voltage needs to be charged does not occur.

Because the bidirectional conduction chip 1 can control magnitude of a current flowing between the first input pin IN and the second input pin OUT, that is, constant current protection can be implemented for currents regardless of whether the first battery or the second battery Battery2 supplies power to the outside or is charged with a voltage of an external power supply, and precharging, constant current regulation, and overcharge prevention of a battery can be implemented when the first battery Battery1 or the second battery Battery2 is charged with the voltage of the. This not only ensures that no large current occurs when the first battery Battery1 and the second battery Battery2 are shorted, preventing path heating or burning of some circuit nodes, but also improves the safety of battery charging and discharging.

In this embodiment of the present invention, because the bidirectional conduction chip 1 enables a battery with a higher voltage to charge a battery with a lower voltage, allows both batteries to supply power to the system load 3 when their battery voltages are equal, and allows the charging management chip 2 to supply power to both batteries simultaneously, battery balancing between the first battery Battery1 and the second battery Battery2 is significantly improved.

In addition to being applied to a circuit system with dual batteries, the bidirectional conduction chip can be further applied to a circuit system with a supercapacitor. The circuit system with the supercapacitor includes the following structures:
the bidirectional conduction chip provided in the previous embodiment;
a supercapacitor, where a charging terminal of the supercapacitor is connected to a second input pin of the bidirectional conduction chip, and because the supercapacitor may use a conventional technical means in the prior art, a specific structure of the supercapacitor is not described again; and
a charging power supply, where a voltage output terminal of the charging power supply is connected to a first input pin of the bidirectional conduction chip. The charging power supply is specifically a voltage source inside the system. Details are not described herein again.

In a system application of the supercapacitor, the bidirectional conduction chip can also implement constant current protection for charging and discharging and zero-current cutoff when a voltage difference between the supercapacitor and the charging power supply is low. A specific technical principle is similar to that of a circuit system with dual batteries. Details are not described herein again.

Certainly, the bidirectional conduction chip may also be applied to another circuit system that needs to be charged and discharged. Details are not described herein again.

An embodiment of the present invention further provides an electronic device, and the electronic device includes any one of the foregoing circuit systems.

Finally, it should be noted that the foregoing embodiments are merely used to describe the technical solutions of the present invention, but are not intended to limit the technical solutions. Although the present invention is described in detail with reference to the foregoing embodiments, a person of ordinary skill in the art should understand that the technical solutions recorded in the foregoing embodiments can still be modified, or equivalent replacements can be made to some or all technical features in the technical solutions. However, these modifications or replacements do not make the essence of the corresponding technical solutions depart from the scope of the technical solutions in the embodiments of the present invention.

1. A bidirectional conduction chip, wherein the bidirectional conduction chip is integrated with the following:
a MOS switching transistor, wherein a first terminal of the MOS switching transistor is connected to a first input pin of the bidirectional conduction chip, a second terminal of the MOS switching transistor is connected to a second input pin of the bidirectional conduction chip, and the MOS switching transistor controls an on/off state of the MOS switching transistor based on a first current or a second current at a gate of the MOS switching transistor;
a first transconductance operational amplifier and a first voltage source, wherein an output terminal of the first transconductance operational amplifier is connected to the gate of the MOS switching transistor and outputs the first current, an inverting input pin of the first transconductance operational amplifier is connected to the first input pin, a non-inverting input pin of the first transconductance operational amplifier is connected to a positive electrode of the first voltage source, and a negative electrode of the first voltage source is connected to the second input pin;
a second transconductance operational amplifier and a second voltage source, wherein an output terminal of the second transconductance operational amplifier is also connected to the gate of the MOS switching transistor and outputs the second current, a non-inverting input pin of the second transconductance operational amplifier is connected to a positive electrode of the second voltage source, a negative electrode of the second voltage source is connected to the first input pin, an inverting input pin of the second transconductance operational amplifier is connected to the second input pin, and an output voltage of the second voltage source and an output voltage of the first voltage source are the same and both are used to represent a preset stable voltage between the first input pin and the second input pin; and
an enabling unit, wherein the enabling unit is configured to:
when a first voltage at the first input pin is greater than a second voltage at the second input pin, output a first enable signal to enable the first transconductance operational amplifier, and output a second enable signal to disable the second transconductance operational amplifier; and
when the first voltage is less than the second voltage, output a second enable signal to enable the second transconductance operational amplifier, and output a first enable signal to disable the first transconductance operational amplifier.

2. The bidirectional conduction chip according to claim 1, wherein the enabling unit comprises a first comparator and an inverter, an output terminal of the first comparator is separately connected to an input pin of the inverter and an enabling terminal of the second transconductance operational amplifier, a non-inverting input pin of the first comparator is connected to the second input pin, an inverting input pin of the first comparator is connected to the first input pin, and an output terminal of the inverter is connected to an enabling terminal of the first transconductance operational amplifier; and
both the first transconductance operational amplifier and the second transconductance operational amplifier are enabled at a high level.

3. The bidirectional conduction chip according to claim 2, further comprising a first switch, wherein a first terminal of the first switch is connected to a substrate terminal of the MOS switching transistor, a second terminal of the first switch is connected to the first terminal of the MOS switching transistor, a third terminal of the first switch is connected to the second terminal of the MOS switching transistor, a control terminal of the first switch is connected to the output terminal of the first comparator, and the first switch is configured to:
connect the first terminal and the third terminal of the first switch based on a high level; and
connect the first terminal and the second terminal of the first switch based on a low level.

4. The bidirectional conduction chip according to claim 1, further comprising a current limiting control module, a constant current regulation module, a constant current regulation pin, and a driving module, wherein
the current limiting control module is configured to output a first control signal to an input terminal of the driving module;
the constant current regulation module is configured to:
output a second control signal to the input terminal of the driving module when the second voltage is less than a precharge threshold voltage;
output a third control signal to the input terminal of the driving module when the second voltage is greater than or equal to the precharge threshold voltage; and
output a fourth control signal to the input terminal of the driving module after a delay of first specified time when the second voltage is greater than or equal to a preset upper-limit voltage;
the constant current regulation pin is connected to a control terminal of the driving module; and
an output terminal of the driving module is connected to the gate of the MOS transistor, and the driving module is configured to:
limit a current from the second input pin to the first input pin within a first current limiting value based on the first control signal;
control a current from the first input pin to the second input pin to be constant at a precharge current based on the second control signal;
control the current from the first input pin to the second input pin to be constant at a preset constant current based on the third control signal and impedance to ground of the constant current regulation pin; and
turn off the MOS switching transistor based on the fourth control signal.

5. The bidirectional conduction chip according to claim 4, wherein the constant current regulation module comprises a voltage division unit, a second comparator, and a third comparator;
the voltage division unit is configured to divide the second voltage and output a divided voltage;
both a non-inverting input pin of the second comparator and a non-inverting input pin of the third comparator are connected to the divided voltage, an inverting input pin of the second comparator is connected to a first reference voltage, an inverting input pin of the third comparator is connected to a second reference voltage, an output terminal of the second comparator and an output terminal of the third comparator are both connected to the current limiting control module, the first reference voltage is less than the second reference voltage, the first reference voltage is used to represent the precharge threshold voltage, and the second reference voltage is used to represent the preset upper-limit voltage;
if the divided voltage is less than the first reference voltage, both the second comparator and the third comparator output a low level, and the second control signal comprises two low-level signals;
if the divided voltage is greater than or equal to the first reference voltage and less than the second reference voltage, the second comparator outputs a high level, the third comparator outputs a low level, and the third control signal comprises one low-level signal and one high-level signal; and
if the divided voltage is greater than or equal to the second reference voltage, both the second comparator and the third comparator output a high level, and the fourth control signal comprises two high-level signals.

6. The bidirectional conduction chip according to claim 4, further comprising a turn-off unit, wherein the turn-off unit is configured to pull the constant current regulation pin to a high level based on a turn-off signal that is externally input to the constant current regulation pin, so that the driving module turns off the MOS switching transistor.

7. The bidirectional conduction chip according to claim 1, wherein the MOS switching transistor is a PMOS transistor, a gate of the PMOS transistor is the gate of the MOS switching transistor, a source of the PMOS transistor is the first terminal of the MOS switching transistor, and a drain of the PMOS transistor is the second terminal of the MOS switching transistor.

8. The bidirectional conduction chip according to claim 1, wherein the MOS switching transistor is an NMOS transistor, a gate of the NMOS transistor is the gate of the MOS switching transistor, a source of the NMOS transistor is the second terminal of the MOS switching transistor, and a drain of the NMOS transistor is the first terminal of the MOS switching transistor;
the chip is further integrated with a charge pump, and the charge pump is configured to improve a capability of driving the gate of the NMOS transistor;
the inverting input pin of the first transconductance operational amplifier is connected to the positive electrode of the first voltage source instead, and the non-inverting input pin of the first transconductance operational amplifier is connected to the first input pin instead; and
the inverting input pin of the second transconductance operational amplifier is connected to the positive electrode of the second voltage source instead, and the non-inverting input pin of the first transconductance operational amplifier is connected to the second input pin instead.

9. A circuit system, comprising:
two bidirectional conduction chips according to any one of claims 4 to 8;
a first battery and a second battery, wherein the first battery and the second battery each correspond to one of the bidirectional conduction chips, a positive electrode of the first battery and a positive electrode of the second battery each are connected to a second input pin of a corresponding bidirectional conduction chip, and both a negative electrode of the first battery and a negative electrode of the second battery are connected to a ground terminal;
a charging management chip and a system load, wherein a first pin of the charging management chip is respectively connected to first input pins of the two bidirectional conduction chips, a power input pin of the charging management chip is connected to an externally input power voltage, the charging management chip is configured to perform path management on the power voltage and charge the first battery and the second battery, a power supply terminal of the system load is connected to a second pin of the charging management chip, and the first pin and the second pin of the charging management chip are coupled by using an internal power supply control switch of the charging management chip; and
a first constant current regulation resistor and a second constant current regulation resistor, wherein the first constant current regulation resistor and the second constant current regulation resistor respectively correspond to one of the bidirectional conduction chips, a first terminal of the first constant current regulation resistor and a first terminal of the second constant current regulation resistor each are connected to a constant current regulation pin of a corresponding bidirectional conduction chip, and both the first terminal of the first constant current regulation resistor and the first terminal of the second constant current regulation resistor are connected to the ground terminal.

10. A circuit system, comprising:
the bidirectional conduction chip according to any one of claims 4 to 8;
a supercapacitor, wherein a charging terminal of the supercapacitor is connected to a second input pin of the bidirectional conduction chip; and
a charging power supply, wherein a voltage output terminal of the charging power supply is connected to a first input pin of the bidirectional conduction chip.

11. The bidirectional conduction chip according to claim 3, further comprising a current limiting control module, a constant current regulation module, a constant current regulation pin, and a driving module, wherein
the current limiting control module is configured to output a first control signal to an input terminal of the driving module;
the constant current regulation module is configured to:
output a second control signal to the input terminal of the driving module when the second voltage is less than a precharge threshold voltage;
output a third control signal to the input terminal of the driving module when the second voltage is greater than or equal to the precharge threshold voltage; and
output a fourth control signal to the input terminal of the driving module after a delay of first specified time when the second voltage is greater than or equal to a preset upper-limit voltage;
the constant current regulation pin is connected to a control terminal of the driving module; and
an output terminal of the driving module is connected to the gate of the MOS transistor, and the driving module is configured to:
limit a current from the second input pin to the first input pin within a first current limiting value based on the first control signal;
control a current from the first input pin to the second input pin to be constant at a precharge current based on the second control signal;
control the current from the first input pin to the second input pin to be constant at a preset constant current based on the third control signal and impedance to ground of the constant current regulation pin; and
turn off the MOS switching transistor based on the fourth control signal.

12. The bidirectional conduction chip according to claim 11, further comprising a turn-off unit, wherein the turn-off unit is configured to pull the constant current regulation pin to a high level based on a turn-off signal that is externally input to the constant current regulation pin, so that the driving module turns off the MOS switching transistor.
